(19) United States
(12) Patent Application Publication
(10) Pub. No.: US 2026/0047306 A1
(43) Pub. Date: Feb. 12, 2026

(54) Display Apparatus

(71) Applicant: LG Display Co., Ltd., Seoul (KR)

(72) Inventors: Ha Ye Kim, Paju-si (KR); Bae Keun Yoo, Paju-si (KR)

(21) Appl. No.: 19/278,620

(22) Filed: Jul. 23, 2025

(30) Foreign Application Priority Data
Aug. 8, 2024 (KR) 10-2024-0106041

(51) Int. Cl. H10K 59/38; H10K 59/80

(52) U.S. Cl. CPC H10K 59/38; H10K 59/8792

(57) ABSTRACT

Disclosed herein is a display apparatus. The display apparatus includes an optical element configured to emit light to outside or sense light from the outside, and a display panel including a first area including a first light-emitting area and a second area including a second light-emitting area and a light transmitting area, wherein the second area includes a color filter overlapping structure, and the color filter overlapping structure includes a first color filter and a second color filter arranged to overlap the first color filter in a thickness direction of the display panel.

### CROSS-REFERENCE TO RELATED APPLICATION

This application claims priority to and the benefit of Korean Patent Application No. 10-2024-0106041, filed on Aug. 8, 2024, the disclosure of which is incorporated herein by reference in its entirety.

### BACKGROUND

### Field

The present specification relates to a display apparatus.

### Discussion of Related Art

An electroluminescence display may be classified into an inorganic electroluminescence display apparatus and an organic electroluminescence display apparatus according to the material of a light-emitting layer. An active matrix type-organic electroluminescence display apparatus includes a self-emissive organic light-emitting diode (hereinafter referred to as “OLED”) and has advantages such as fast response speed, high luminous efficiency, high brightness, and wide viewing angles. In the organic electroluminescence display apparatus, an organic light-emitting diode (OLED) is formed in each of pixels. The organic electroluminescence display apparatus may not only have fast response speed, high luminous efficiency, high brightness, and wide viewing angles but also provide excellent contrast ratio and color reproduction because black grayscale can be expressed as true black.

Recently, various optical elements are added to mobile terminals. The optical elements may include sensors or lighting devices required for supporting a multimedia function or performing a biometric function. The optical elements may be assembled under a display panel. In order to enlarge the screen of a mobile terminal, the corresponding optical element may be arranged in a notch area designed to be recessed in the upper portion of the screen of the display panel, or within a punch hole formed in the screen. Because such an optical element is arranged in the notch area or within the punch hole, the function thereof is limited.

### SUMMARY

The present specification is directed to addressing the foregoing needs and/or solving the problems encountered in the related art.

Objectives according to embodiments of the present specification are not limited to the above-described objectives, and other objectives that are not described herein will be apparently understood by those skilled in the art from the following description.

A display apparatus according to an embodiment of the present specification may include an optical element configured to emit light to outside or sense light from the outside, and a display panel including a first area including a first light-emitting area and a second area including a second light-emitting area and a light transmitting area, wherein the second area includes a color filter overlapping structure, and wherein the color filter overlapping structure includes a first color filter and a second color filter arranged to overlap the first color filter in a thickness direction of the display panel.

According to various embodiments of the present specification, the second area may further include a black matrix.

According to various embodiments of the present specification, the second area may further include a metal overlapping structure including a slit, and the slit may be arranged to overlap the color filter overlapping structure in the thickness direction.

According to various embodiments of the present specification, the second light-emitting area may include a first metal overlapping structure including a first slit, and the first slit may be arranged to overlap the color filter overlapping structure in the thickness direction.

According to various embodiments of the present specification, the light transmitting area may include a second metal overlapping structure including a second slit.

According to various embodiments of the present specification, the second area may further include a black matrix, the first metal overlapping structure may include a first-first metal overlapping structure including a first-first slit and a first-second metal overlapping structure including a first-second slit, the first-first slit is arranged to overlap the color filter overlapping structure in the thickness direction, and the first-second slit is arranged to overlap the black matrix in the thickness direction.

According to various embodiments of the present specification, the light transmitting area may include a second metal overlapping structure including a second slit.

According to various embodiments of the present specification, the second slit may be arranged to overlap the color filter overlapping structure in the thickness direction.

According to various embodiments of the present specification, the second slit may be arranged to overlap the black matrix in the thickness direction.

According to various embodiments of the present specification, the color filter overlapping structure may further include a third color filter arranged to overlap the second color filter in the thickness direction.

A display apparatus according to an embodiment of the present specification may include an optical element configured to emit light to outside or sense light from the outside, and a display panel including a first area including a plurality of pixels and a second area including a plurality of pixels and a light transmitting area, wherein each of the first area and the second area includes a color filter overlapping structure, and wherein the color filter overlapping structure in the second area has a second density different from a first density of the color filter overlapping structure in the first area.

According to various embodiments of the present specification, the second density may be greater than the first density.

According to various embodiments of the present specification, the second density may be an area of the color filter overlapping structure per second unit pixel arranged in the second area, and the first density may be an area of the color filter overlapping structure per first unit pixel arranged in the first area.

According to various embodiments of the present specification, a number of pixels included in the first unit pixel may be identical to a number of pixels included in the second unit pixel.

According to various embodiments of the present specification, the first density may change in a direction from the second area to the first area.

According to various embodiments of the present specification, the first density may decrease in a direction from the second area to the first area.

According to various embodiments of the present specification, the color filter overlapping structure may include a first color filter and a second color filter arranged to overlap the first color filter in a thickness direction of the display panel.

According to various embodiments of the present specification, each of the first area and the second area may further include a black matrix.

According to various embodiments of the present specification, each of the first area and the second area may include a metal overlapping structure including a slit, and the slit may be arranged to overlap the color filter overlapping structure in the thickness direction.

According to various embodiments of the present specification, each of the first area and the second area may include a first metal overlapping structure including a first slit, the light transmitting area may include a second metal overlapping structure including a second slit, and the first slit may be arranged to overlap the color filter overlapping structure in the thickness direction.

According to the present specification, an improvement in the sensing quality of optical elements may be achieved.

According to the present specification, the reflective color tone of a display apparatus may be improved, and the clarity of images may be enhanced.

According to the present specification, the diffraction of light may be solved, and the transmittance of first light may be improved while a phenomenon in which a second area is visually perceived (i.e., a boundary visibility phenomenon) may be reduced.

According to the present specification, there can be provided a display apparatus, which has improved first light transmittance and enhances reflective color tone and color reproduction, and which reduces a phenomenon in which a boundary between areas is visually perceived, thereby obtaining advantages in terms of design.

### BRIEF DESCRIPTION OF THE DRAWINGS

The above and other objects, features, and advantages of the present specification will become more apparent to those of ordinary skill in the art by describing exemplary embodiments thereof in detail with reference to the attached drawings, in which:

FIG. 1 is a cross-sectional view schematically illustrating a display apparatus according to an embodiment of the present specification.

FIG. 2 is a diagram illustrating an optical element overlapping with the second area of the display apparatus according to an embodiment of the present specification.

FIG. 3 is a diagram illustrating one example of optical elements arranged in a second area and a notch area of the display apparatus according to an embodiment of the present specification.

FIG. 4 is a block diagram illustrating the display apparatus according to an embodiment of the present specification.

FIG. 5 is a diagram illustrating an example in which the display apparatus according to an embodiment of the present specification is applied to a mobile terminal.

FIG. 6 is a plan view illustrating pixel arrangement in a first area according to an embodiment of the present specification.

FIG. 7 is a plan view illustrating pixel arrangement in a second area according to an embodiment of the present specification.

FIGS. 8 to 11 are schematic sectional views illustrating a display apparatus according to an embodiment of the present specification.

FIG. 12 is a graph illustrating transmittance according to the wavelength band of light in color filters, a pixel defining layer, and a black matrix.

FIG. 13 is a table illustrating image clarity and transmittance according to an embodiment.

FIG. 14 is a diagram illustrating a structure in which black matrices are arranged over slits to improve visibility under external light.

FIG. 15 is a diagram illustrating a structure in which color filter overlapping structures are arranged over slits to degrade visibility under external light.

FIG. 16 is a schematic sectional view illustrating a display apparatus according to an embodiment of the present specification.

FIG. 17 is a partially enlarged view illustrating an enlarged portion P of FIG. 7.

FIG. 18 is a partially enlarged view illustrating an enlarged portion P of FIG. 7 in which a black matrix is arranged in a first slit.

FIG. 19 is a partially enlarged view illustrating an enlarged portion P of FIG. 7 in which a black matrix is not arranged in a first slit.

FIG. 20 is a table illustrating image clarity and transmittance in embodiments illustrated in FIGS. 18 and 19.

FIG. 21 is a plan view illustrating a display apparatus according to another embodiment of the present specification.

FIG. 22 is a sectional view taken along line I-II of FIG. 21 in a structure in which black matrices are arranged in slits.

FIG. 23 is a sectional view taken along line I-II of FIG. 21 in a structure in which color filter overlapping structures are arranged in slits.

FIG. 24 is a sectional view taken along line I-II of FIG. 21 in a structure in which a color filter overlapping structure and a black matrix are arranged in slits.

FIG. 25 is a plan view illustrating FIG. 18 with section line III-IV.

FIG. 26 is a sectional view taken along line III-IV of FIG. 25 in a structure in which black matrices are arranged in slits.

FIG. 27 is a sectional view taken along line III-IV of FIG. 25 in a structure in which color filter overlapping structures are arranged in slits.

FIG. 28 is a sectional view taken along line III-IV of FIG. 25 in a structure in which a color filter overlapping structure and a black matrix are arranged in slits.

FIG. 29 is a plan view illustrating pixels according to an embodiment of the present specification.

FIG. 30 is a plan view illustrating a display apparatus in which pixels are arranged according to an embodiment of the present specification.

FIG. 31 is a plan view illustrating a display apparatus according to another embodiment of the present specification.

### DETAILED DESCRIPTION OF EXEMPLARY EMBODIMENTS

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The present disclosure is only defined within the scope of the accompanying claims.

In describing the present disclosure, if it is determined that the detailed description of the related known technology may unnecessarily obscure the subject matter of the present disclosure, the detailed description thereof will be omitted.

When “include”, “have”, “consist”, or the like mentioned in the present specification, other parts may be added unless “only” is used. In the case where the component is expressed in the singular, it may include the plural unless specifically stated otherwise.

When describing a positional or interconnected relationship between two components by using terms such as “on top of”, “above”, “below”, “next to”, “connect or couple with”, “crossing”, “intersecting” etc., one or more other components may be interposed between them unless “immediately” or “directly” is used.

When describing a temporal contextual relationship is described by using terms such as “after”, “following”, “next to” or “before”, it may not be continuous on a time scale unless “immediately” or “directly” is used.

The terms “first”, “second” and the like may be used to distinguish components from each other, but the functions or structures of the components are not limited by ordinal numbers or component names in front of the components.

The following embodiments may be combined or associated with each other in whole or in part, and various types of interlocking and driving are technically possible. The embodiments may be implemented independently of each other or together in an interrelated relationship.

Terms (including technical and scientific terms) used in the embodiments of the present specification may be interpreted in meanings commonly understood by those skilled in the art to which the present disclosure pertains, unless explicitly and specifically defined otherwise, and commonly used terms, such as predefined terms, may be interpreted in consideration of their contextual meanings of the related technology.

Hereinafter, embodiments of the present specification will be described in detail with reference to the accompanying drawings.

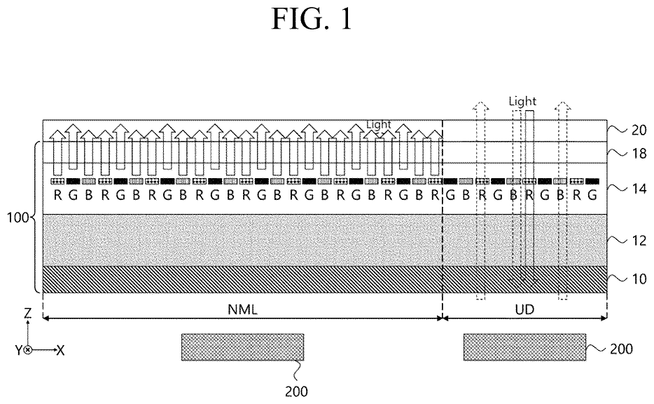

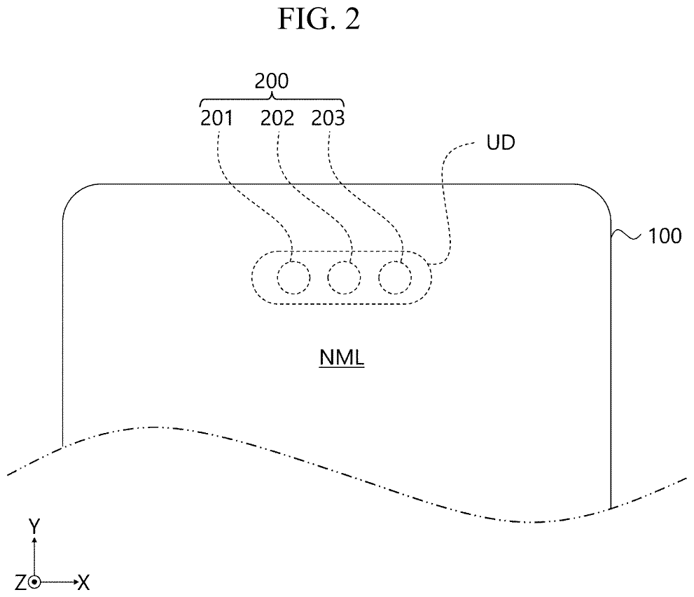

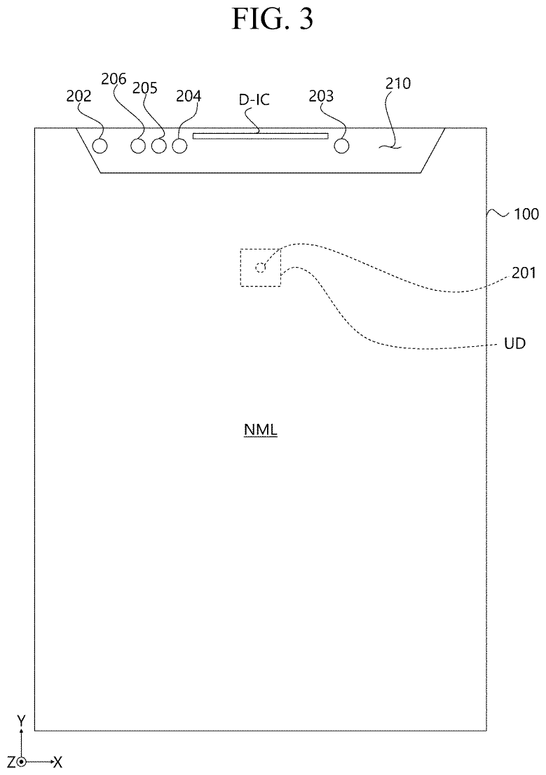

FIG. 1 is a cross-sectional view schematically illustrating a display apparatus according to an embodiment of the present specification. FIG. 2 is a diagram illustrating an optical element overlapping with the second area of the display apparatus according to an embodiment of the present specification. FIG. 3 is a diagram illustrating one example of optical elements arranged in a second area and a notch area of the display apparatus according to an embodiment of the present specification.

Referring to FIGS. 1 to 3, a pixel array constituting a screen of a display panel 100 according to an embodiment of the present specification may include a first area NML and a second area UD. The first area NML and the second area UD include pixels on which pixel data of an input image is written. The input image may be displayed in the first area NML and the second area UD.

The first area NML may be a display area in which a plurality of pixels are arranged to reproduce the input image. The first area NML may be a main display area of the screen that is larger than the second area UD and displays most of the images.

The second area UD may be a display area in which a plurality of pixels are arranged to reproduce the input image. The pixel density or resolution of the second area UD may be the same or lower than that of the first area NML. The pixel density may be interpreted as pixels per inch (PPI). The second area UD may have a lower pixel density than the first area NML due to the placement of a light transmitting area.

The second area UD may include, but is not limited to, a plurality of light transmitting areas without a medium that blocks light. The light transmitting areas may be disposed between sub-pixels. Light can pass through the light transmitting areas with little loss. The light may include, but is not limited to, visible light, infrared light, ultraviolet light, etc. If the light transmitting area of the second area UD is enlarged to increase the amount of light incident on the optical element through the second area UD, the pixel density or resolution of the second area UD may be smaller than the pixel density or resolution of the first area NML because the pixel density is reduced due to the light transmitting area.

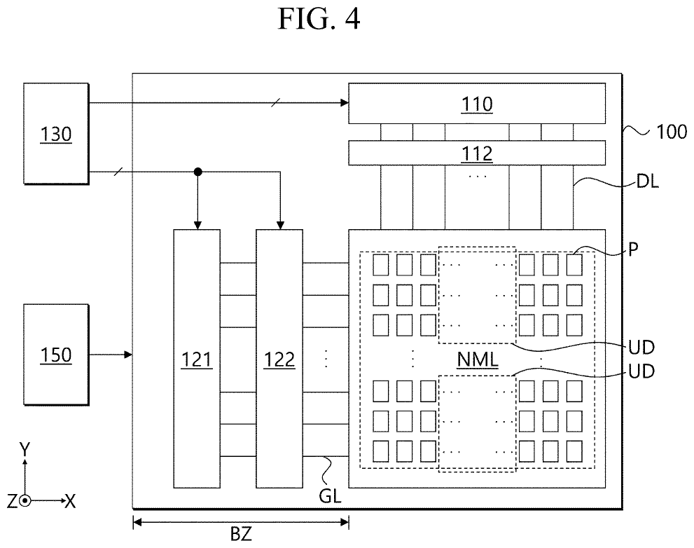

Each of the pixels P (see FIG. 4) in the first area NML and the second area UD may include sub-pixels of different colors to achieve the color of the image. The sub-pixels may include red, green, and blue sub-pixels. Hereinafter, the red sub-pixels may be abbreviated as “R sub-pixels”, the green sub-pixels as “G sub-pixels”, and the blue sub-pixels as “B sub-pixels”. Each of the pixels P may further include a white sub-pixel (hereinafter abbreviated as a “W sub-pixel”). Each of the sub-pixels may include a pixel circuit for driving light-emitting elements.

At least one optical element 200 may be arranged under the rear surface of the display panel 100 to overlap the first area NML of the display panel 100. Internal light from the optical element 200 may proceed through the first area NML to an object outside the display apparatus.

At least one optical element 200 may be arranged under the rear surface of the display panel 100 to overlap the second area UD of the display panel 100. External light may proceed through the second area UD to the optical element 200 arranged under the display panel 100.

The optical element 200 may include one or more of an image sensor (or a third optical element), a proximity sensor, a white light illumination element, and an optical element for facial recognition. The optical element 200 may be configured to emit light to outside or sense light from the outside.

The optical element for face recognition may include a first optical element, a second optical element, an infrared lighting element, and the like disposed under the second area UD of the display panel 100.

Referring to FIG. 3, a second optical element 202, a third optical element 203, an ambient light sensor 204, a proximity sensor 205, and a flood illuminator 206 may be disposed in a notch area 210 of the mobile terminal, and a first optical element 201 may be disposed in the second area UD. The notch area 210 may be a non-display area with no pixels at the top of the screen of the mobile terminal.

In the display apparatus according to the present specification, since the optical elements 200 are arranged under the rear surface of the display panel 100 to overlap the second area UD, the display area of the screen may not be limited due to the optical elements 200. Therefore, the display apparatus according to the present specification may realize a screen of a full-screen display by enlarging the display area of the screen, and the degree of freedom in screen design may be increased.

The display panel 100 may have a width in the X-axis direction, a length in the Y-axis direction, and a thickness in the Z-axis direction. The X-axis direction and the Y-axis direction may intersect each other in the plane of the display panel 100. For example, the X-axis direction and the Y-axis direction may be orthogonal to each other.

The display panel 100 may include a circuit layer 12 arranged on a substrate and a light-emitting element layer 14 arranged on the circuit layer 12. A polarizer 18 may be arranged on the light-emitting element layer 14, and a cover glass 20 may be arranged on the polarizer 18.

The circuit layer 12 may include a pixel circuit connected to wires such as data lines, gate lines intersecting the data lines, and power lines, and a gate driver connected to the gate lines. The circuit layer 12 may include transistors implemented as thin film transistors (TFT), and circuit elements such as capacitors. The wires and circuit elements of the circuit layer 12 may be implemented with a plurality of insulating layers, two or more metal layers separated with an insulating layer therebetween, and an active layer including a semiconductor material.

The light-emitting element layer 14 may include light-emitting elements driven by the pixel circuit. The light emitting element may be implemented as an organic light emitting diode OLED. The OLED may include an organic compound layer formed between an anode and a cathode. The organic compound layer may include, but is not limited to, a hole injection layer (HIL), a hole transport layer (HTL), an emission layer (EML), an electron transport layer (ETL), and an electron injection layer (EIL). When a voltage is applied to an anode electrode (ANO) and a cathode electrode (CAT) of the OLED, holes passing through the hole transport layer (HTL) and electrons passing through the electron transport layer (ETL) are moved to the emission layer (EML) to form excitons, resulting in the emission of visible light from the emission layer (EML). The OLED used as the light-emitting element may have a tandem structure in which a plurality of light-emitting layers are stacked. The OLED having the tandem structure may improve the luminance and lifespan of the pixels. The light-emitting element layer 14 may further include an array of color filters disposed over the light-emitting elements to selectively transmit wavelengths of red, green, and blue light.

The light-emitting element layer 14 may be covered with a protective layer and the protective layer may be covered with an encapsulation layer. The protective layer and the encapsulation layer may have a structure in which an organic film and an inorganic film are alternately stacked. The inorganic film may block the penetration of moisture and oxygen. The organic film may planarize the surface of the inorganic film. When the organic film and the inorganic film are stacked in multiple layers, the movement path of moisture or oxygen becomes longer than that of a single layer, so that penetration of moisture/oxygen affecting the light-emitting element layer 14 may be effectively blocked.

A touch sensor layer (not shown) is formed on the encapsulation layer, and the polarizer 18 or a color filter layer may be disposed on the touch sensor layer. The touch sensor layer may include capacitive touch sensors that sense a touch input based on the change in capacitance before and after the touch input. The touch sensor layer may include metal wire patterns and insulating films that form the capacitance of the touch sensors. The insulating films may insulate portions where the metal wire patterns are intersected, and may planarize the surface of the touch sensor layer.

The polarizer 18 may improve visibility and contrast ratio by converting the polarization of external light reflected by metals of the touch sensor layer and the circuit layer. The polarizer 18 may be implemented as a polarizing plate or circular polarizing plate in which a linear polarizing plate and a phase retardation film are bonded. A cover glass 20 may be bonded on the polarizer 18. A color filter layer disposed over the touch sensor layer may include red, green, and blue color filters. The color filter layer may further include a black matrix pattern. However, it is not limited thereto, and the color filter layer according to an embodiment of the present specification may further include a color filter overlapping structure. The color filter layer may replace the role of the polarizer 18 and increase the color purity of an image reproduced in the pixel array by absorbing a portion of the wavelength of the light reflected from the circuit layer and the touch sensor layer. In this case, the polarizer 18 may not be disposed. The above-described configurations will be described in more detail in the following cross-sectional views.

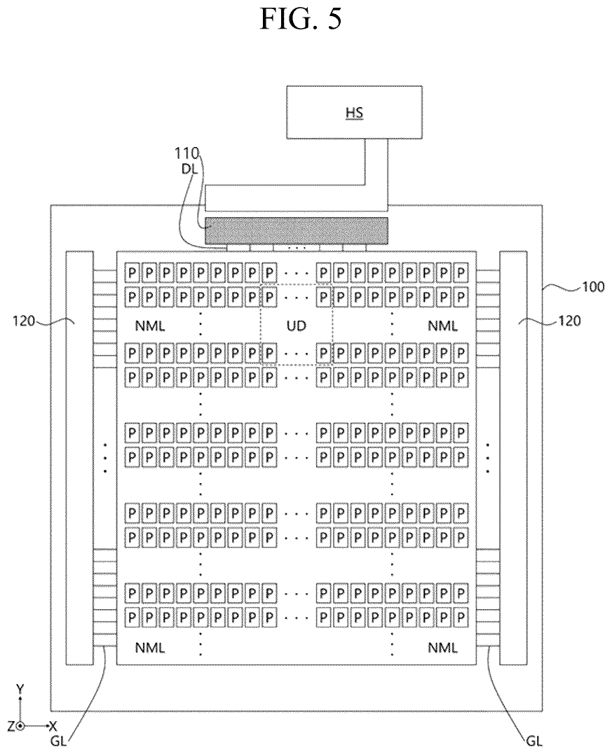

FIG. 4 is a block diagram illustrating the display apparatus according to an embodiment of the present specification. FIG. 5 is a diagram illustrating an example in which the display apparatus according to an embodiment of the present specification is applied to a mobile terminal.

Referring to FIGS. 4 and 5, the display apparatus according to an embodiment of the present specification may include a display panel 100, display panel drivers 110 and 120 for writing pixel data of an input image into pixels P of the display panel 100, a timing controller 130 for controlling the display panel drivers, and a power supply 150 for generating power required for driving the display panel 100.

The display panel 100 may include a pixel array that displays an input image on a screen. The pixel array may be divided into the first area NML and the second area UD as described above.

Touch sensors may be arranged on the screen of the display panel 100.

The display panel 100 may be implemented as a flexible display panel in which pixels P are arranged on a flexible substrate such as a plastic substrate or a metal substrate.

The display panel driver may reproduce the input image on the screen of the display panel 100 by writing the pixel data of the input image to the sub-pixels. The display panel driver may include the data driver 110 and the gate driver 120. The display panel driver may further include a demultiplexer 112 disposed between the data driver 110 and the data lines DL.

The display panel driver may operate in low-speed driving mode under the control of the timing controller 130.

The data driver 110 may generate a data voltage (Vdata) by converting the pixel data of the input image, which is digital data, using a digital-to-analog converter (hereinafter referred to as “DAC”). The data voltage (Vdata) outputted from each of the channels of the data driver 110 may be supplied to the data lines DL of the display panel 100, or may be supplied to the data lines DL through the demultiplexer 112.

The demultiplexer 112 may time divide and distribute the data voltage Vdata output through the channels of the data driver 110 to a plurality of data lines DL. The demultiplexer 112 may allow the number of channels of the data driver 110 to be reduced.

The gate driver 120 may sequentially supply the gate signal to the gate lines GL by shifting the gate signals using a shift register.

The gate driver 120 may be arranged on each of the left and right bezel areas of the display panel 100 to supply the gate signal to the gate lines GL in a single feeding method.

The gate driver 120 may include a first gate driver 121 and a second gate driver 122. The first gate driver 121 may output a scan pulse and a sensing pulse, and may shift the scan pulse and the sense pulse according to a shift clock. The second gate driver 122 may output an EM (light emitting) pulse and shift the EM pulse according to a shift clock.

The timing controller 130 may receive pixel data of the input image from a host system and a timing signal synchronized with the pixel data. The timing signal may include a vertical synchronization signal (Vsync), a horizontal synchronization signal (Hsync), a clock (CLK), and a data enable signal (DE).

The timing controller 130 may transmit the pixel data of the input image to the data driver 110 and synchronize the data driver 110 and the demultiplexer 112, and the gate driver 120.

The timing controller 130 control the operation timing of the display panel driving circuit at a frame frequency of an input frame frequency×i (i is a positive integer greater than 0) Hz by multiplying the input frame frequency by i.

The timing controller 130 may generate a data timing control signal for controlling the operation timing of the data driver 110 and a gate timing control signal for controlling the operation timing of the gate driver 120 based on the timing signals such as vertical synchronization signal (Vsync), horizontal synchronization signal (Hsync), and enable signal (DE) received from the host system.

Voltage levels of the gate timing control signals output from the timing controller 130 may be converted into a gate high voltage (VGH/VEH) and a gate low voltage (VGL/VEL) via a level shifter (not shown), which are then supplied to the gate driver 120. The level shifter may receive the clock of the gate timing control signal from the timing controller 130 and output the timing signals required to drive the gate driver 120, such as a start pulse and a shift clock.

The power supply 150 may generate power required for driving the display panel driver and the display panel 100 by adjusting a DC input voltage from the host system. The power supply 150 may output direct current voltages such as gamma reference voltage, gate-off voltage (VGH/VEH), gate-on voltage (VGL/VEL), pixel driving voltage (ELVDD), low potential power voltage (ELVSS), initialization voltage (Vini), and reference voltage (VREF).

The host system HS may be a main circuit board of a television (TV) system, a set-top box, a navigation system, a personal computer (PC), a vehicle system, a home theater system, a mobile device, or a wearable device. The host system HS may include an authentication module.

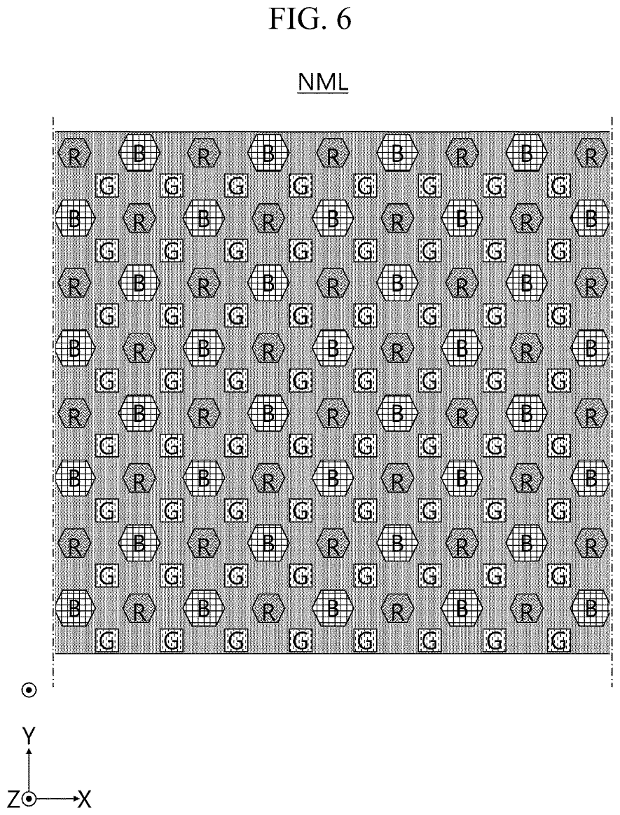

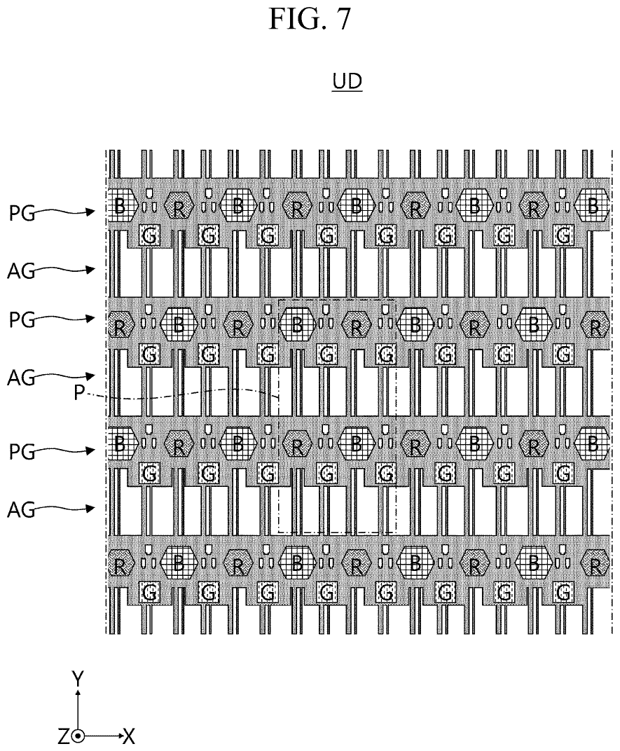

FIG. 6 is a plan view illustrating pixel arrangement in a first area according to an embodiment of the present specification. FIG. 7 is a plan view illustrating pixel arrangement in a second area according to an embodiment of the present specification.

Referring to FIG. 6, a first area NML may include a plurality of pixels. Each of the pixels may be implemented as a real-type pixel in which red (R), green (G), and blue (B) sub-pixels R, G, B corresponding to three primary colors constitute a single pixel. Each of the pixels may further include white (W) sub-pixels omitted in the drawing.

The pixel density or resolution of the first area NML may be higher than the pixel density or resolution of the second area. As will be described later, the reference numeral for the second area is UD.

Each of the pixels may be configured such that two sub-pixels constitute a single pixel using a sub-pixel rendering algorithm. For example, any one pixel may be composed of R and first G sub-pixels R, G, and another pixel may be composed of B and second G sub-pixels B, G. Insufficient color representation in each pixel may be compensated for by averaging pieces of color data among neighboring pixels.

The sub-pixels may exhibit different emission efficiencies of light-emitting elements for respective colors. In consideration of this, the sizes of sub-pixels may differ for respective colors. For example, among R, G, and B sub-pixels R, G, B, the B sub-pixel B is the largest, and the G sub-pixel G may be the smallest. However, the sizes of sub-pixels are not limited thereto.

Referring to FIG. 7, a second area UD may include pixel groups PG spaced apart from each other by a certain distance and light transmitters AG arranged between neighboring pixel groups PG. Due to the light transmitters AG, the distance by which the pixel groups PG are spaced apart from each other in the second area UD may be shorter than the distance by which the pixel groups PG are spaced apart from each other in the first area NML. Each pixel group PG may include a plurality of pixels, each including sub-pixels.

The light transmitters AG may be regions in which pixels are not arranged. The light transmitters AG may be made of transparent insulating materials without including metal wires or pixels. Due to the light transmitters AG, the pixel density of the second area UD may decrease, but the average light transmittance of the second area UD may become higher than that of the first area NML, and thus the amount of light received by optical elements may increase. Light may include wavelength bands corresponding to visible light, infrared light, ultraviolet light, and the like. Although the light transmitters AG are illustrated as having a rounded shape, the shape of the light transmitters AG is not limited thereto. For example, the light transmitters AG may be designed in various shapes, such as circular, elliptical, polygonal, or angular shapes.

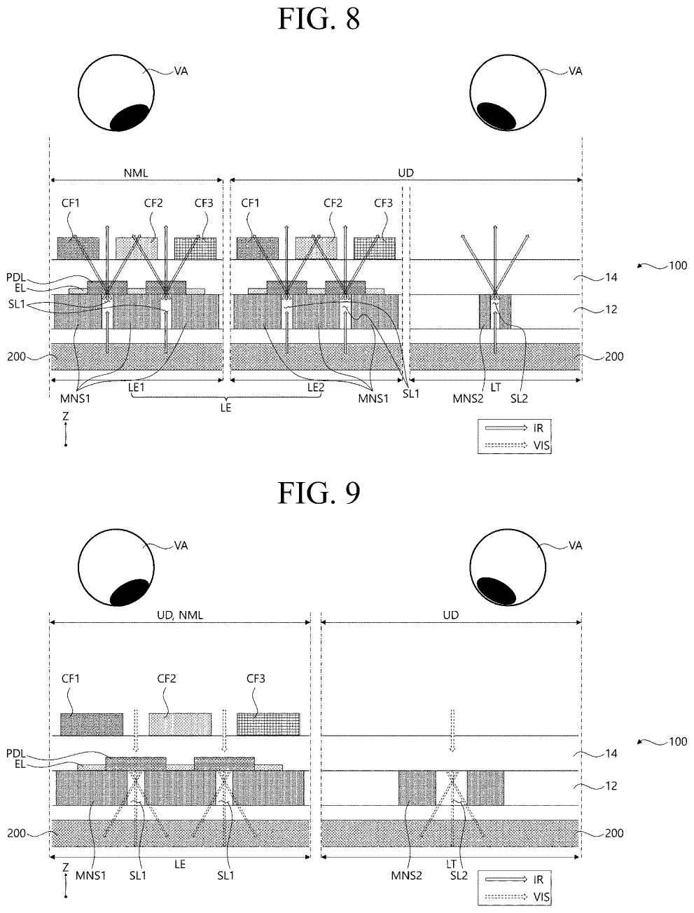

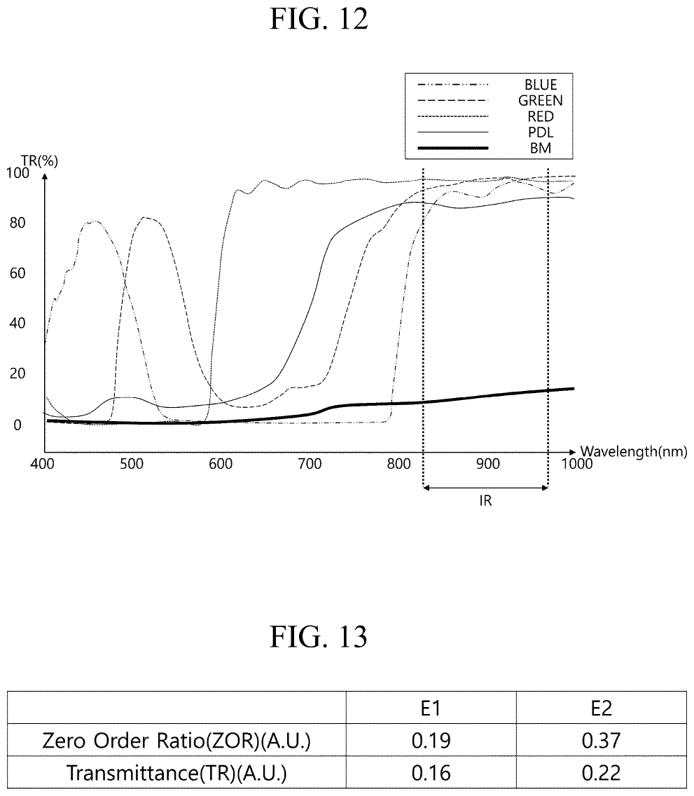

FIGS. 8 to 11 are schematic sectional views illustrating a display apparatus according to an embodiment of the present specification. FIG. 12 is a graph illustrating transmittance TR according to the wavelength band of light in color filters, a pixel defining layer, and a black matrix. FIG. 13 is a table illustrating image clarity and transmittance according to an embodiment.

Referring to FIGS. 8 and 9, a display apparatus according to an embodiment of the present specification may include an optical element 200 and a display panel 100 arranged on the optical element 200. The display panel 100 may include a circuit layer 12, a light-emitting element layer 14, and the like.

According to an embodiment, the display panel 100 may include a first area NML and a second area UD. The first area NML may include a first light-emitting area LE1. The second area UD may include a second light-emitting area LE2 and a light transmitting area LT.

In each of the light-emitting areas LE1 and LE2, a first metal overlapping structure MNS1 may be arranged. A light-emitting element EL and a pixel defining layer PDL may be arranged on the first metal overlapping structure MNS1. The light-emitting element layer 14 may further include the above-described protective layer, encapsulation layer, and the like. A color filter layer including color filters CF1, CF2, and CF3 may be arranged over the light-emitting element EL. In the color filter layer, a black matrix, a color filter overlapping structure, and the like may be further arranged.

The color filter layer may include a first color filter CF1, a second color filter CF2, and a third color filter CF3. Each of the first color filter CF1, the second color filter CF2, and the third color filter CF3 may be implemented such that any one color selected from the group consisting of red, green, and blue does not overlap other colors.

According to an embodiment, the first color filter CF1 may implement a red color, the second color filter CF2 may implement a green color, and the third color filter CF3 may implement a blue color. However, embodiments of the present specification are not limited thereto.

A second metal overlapping structure MNS2 may be arranged in the light transmitting area LT. As illustrated in the drawing, the first metal overlapping structure MNS1 and the second metal overlapping structure MNS2 may be arranged in the circuit layer 12.

The metal overlapping structures MNS1 and MNS2 arranged in the display apparatus according to an embodiment of the present specification may include a plurality of metal layers. Each of the metal overlapping structures MNS1 and MNS2 may further include a semiconductor material. The plurality of metal layers may overlap or may not overlap each other in the planar direction (e.g., in the Z-axis direction or the thickness direction) of the display panel 100. As spaces in which both the metal overlapping structures MNS1 and MNS2 do not overlap each other, slits SL1 and SL2 may be present. For example, the slits SL1 and SL2 may be defined as spaces in which none of a plurality of metal layers present in the circuit layer 12 overlap each other. At least some of the plurality of metal layers may be implemented as driving transistors, and others may be implemented as storage capacitors, but embodiments of the present specification are not limited thereto.

First light IR may be emitted from the optical element 200. However, the present specification is not limited to that illustrated in drawings, and the first light IR may be received by the optical element 200. The optical element 200 may externally receive second light VIS. In an embodiment, the first light IR may be, but is not limited to, light having an infrared wavelength band. In an embodiment, the second light VIS may be, but is not limited to, light having a visible light wavelength band.

The slits SL1 and SL2 formed by the metal overlapping structures MNS1 and MNS2 may cause diffraction of light directed toward or emitted from the optical element 200 due to the narrowness of the width or breadth thereof.

Due to diffraction of light caused by the relatively small gap of each of the slits SL1 and SL2, a phenomenon in which light IR or VIS directed toward the optical element 200 or emitted from the optical element 200 to the outside of the display panel 100 is distorted may occur. As distortion, such as in light transmission performance, occurs, a problem may arise in that light reception performance of a sensor arranged in the optical element 200 deteriorates.

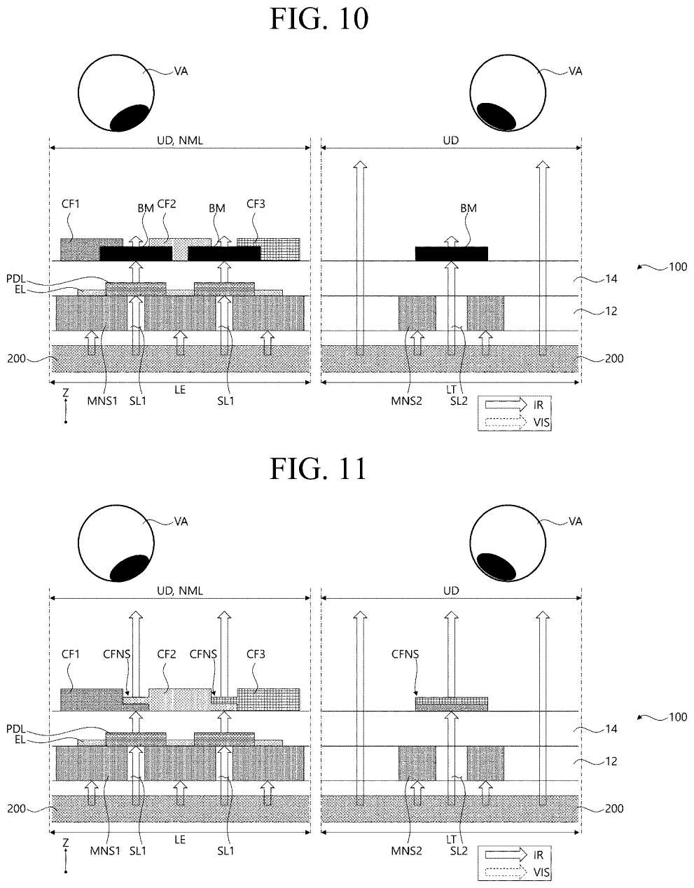

Referring to FIG. 10, in a display apparatus according to an embodiment of the present specification, black matrices BM may be arranged to prevent light distortion or the like. The black matrices BM may be arranged to overlap the pixel defining layer PDL, the slits SL1 and SL2, and the like. The black matrices BM may be arranged over the slits SL1 and SL2. The black matrices BM are arranged to improve the sensor performance of the optical element 200 while external light is absorbed to enhance visibility. The black matrices BM may be arranged in each of the first area NML and the second area UD.

Although the black matrices BM may be arranged in the display apparatus according to the embodiment of the present specification, the transmission performance of the first light IR emitted from the optical element 200 may deteriorate when the black matrices BM are arranged over both the slits SL1 and SL2. Although the first light IR may be light having an infrared wavelength band, embodiments of the present specification are not limited thereto.

As supported by the graph which will be described later, light passing through the slits SL1 and SL2 may be significantly reduced in amount while passing through the black matrices BM. For example, the transmittance of the first light IR through the black matrices BM may range from 10% to 20%. Because the pixel defining layer PDL has relatively high transmittance, a decrease in transmittance to a level that affects performance may not occur before passing through the black matrices BM. However, when the black matrices BM are arranged over the slits SL1 and SL2 for reasons such as improving visibility under external light or preventing diffraction of light, a problem arises in that the transmittance of the first light IR emitted from the optical element 200 or directed toward the optical element 200 from the outside of the optical element 200 is significantly reduced.

Referring to FIG. 11, in a display apparatus according to an embodiment of the present specification, color filter overlapping structures CFNS may be arranged over slits SL1 and SL2 to prevent light distortion or the like. The slits SL1 and SL2 may be arranged to overlap the color filter overlapping structure CFNS in the thickness direction of the display panel 100.

Each of the color filter overlapping structures may include a first color filter CF1 and a second color filter CF2 arranged on the first color filter CF1. The second color filter CF2 may be arranged to overlap the first color filter CF1 in a thickness direction of the display panel 100. Alternatively, each of the color filter overlapping structures may include a second color filter CF2 and a third color filter CF3 arranged on the second color filter CF2. Alternatively, each of the color filter overlapping structures may include a first color filter CF1 and a third color filter CF3 arranged on the first color filter CF1. However, each of the color filter overlapping structures CFNS is not limited thereto, and may be a structure in which a plurality of color filters for implementing three different colors overlap each other. For example, each color filter overlapping structure may be a structure in which all of the first color filter CF1, the second color filter CF2, and the third color filter CF3 overlap each other.

As illustrated in the drawing, each color filter overlapping structure CFNS in which a plurality of color filters for implementing different colors overlap each other may have the transmittance of first light IR higher than that of black matrices. According to the drawing, the amount of first light IR passing through the corresponding color filter overlapping structure CFNS may be proportional to the length of the corresponding arrow. Because transmittance is higher compared to the case where the first light passes through the black matrix, the amount of the first light IR passing through the color filter overlapping structure CFNS relative to the amount of the first light IR incident on the color filter overlapping structure CFNS may be greater than that in the case of the black matrix.

Referring to FIG. 12, all of a color filter RED implementing a red color, a color filter GREEN implementing a green color, a color filter BLUE implementing a blue color, and a pixel defining layer PDL may have transmittance higher than that of a black matrix BM in the wavelength band of first light IR. For example, the wavelength band of the first light IR may be 800 nm or more. Alternatively, the wavelength band may range from 850 nm to 1000 nm. Alternatively, the wavelength band may range from 900 nm to 950 nm.

Referring to FIG. 13, it is verified that both a Zero Order Ratio (ZOR) value indicating image clarity and a Transmittance (TR) value indicating transmittance are improved in an embodiment E2 in which a color filter overlapping structure is arranged over a slit, compared to an embodiment E1 in which a black matrix is arranged over a slit. The “A.U.” in FIG. 13 means an arbitrary unit.

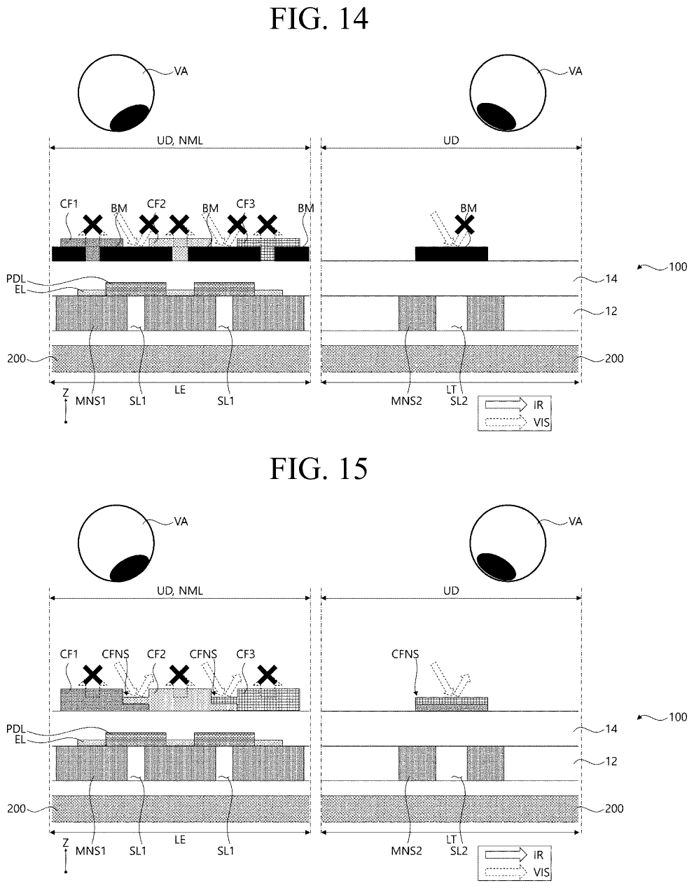

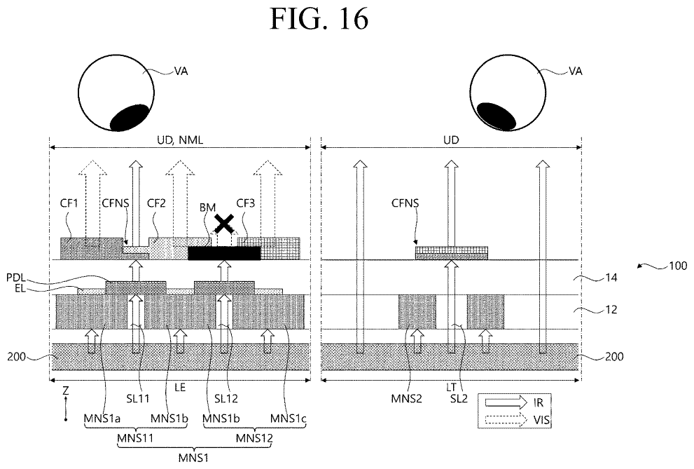

FIG. 14 is a diagram illustrating a structure in which black matrices are arranged over slits to improve visibility under external light. FIG. 15 is a diagram illustrating a structure in which color filter overlapping structures are arranged over slits to degrade visibility under external light. FIG. 16 is a schematic sectional view illustrating a display apparatus according to an embodiment of the present specification.

Referring to FIGS. 14 and 15, in the case where black matrices BM are arranged over slits SL1 and SL2, light emitted from a light-emitting element EL may not pass through an area in which the black matrices BM are arranged. In the case where the color filter overlapping structures CFNS are arranged over the slits SL1 and SL2, light emitted from the light-emitting element EL may pass through an area in which the color filter overlapping structures CFNS are arranged. For example, light emitted from the light-emitting element EL may be second light VIS. The second light VIS may be light having a wavelength band of visible light.

In an embodiment, the black matrices BM may absorb all of the second light VIS, and may have the lowest transmittance for the second light VIS. Each of the color filter overlapping structures CFNS may be a structure in which a plurality of color filters CF1, CF2, and CF3 that selectively convert the second light VIS overlap each other. Therefore, the transmittance of the second light VIS through the color filter overlapping structure CFNS may be lower than that through each of the color filters CF1, CF2, and CF3.

The transmittance of the second light VIS through each black matrix BM may be lower than that through each of the color filters CF1, CF2, and CF3. The transmittance of the second light VIS through the color filter overlapping structure CFNS and the black matrix BM may be lower than that through each of the color filters CF1, CF2, and CF3. Therefore, in an embodiment, the color filter overlapping structure CFNS employed to improve the transmittance of the first light IR may replace the function of the black matrix BM for reducing the transmittance of the second light VIS.

However, because the black matrix BM absorbs most of the second light VIS, the absorption rate of the second light VIS by the color filter overlapping structure CFNS may be lower than that by the black matrix BM.

In the case where the black matrix BM is arranged over each of the slits SL1 and SL2, an area in which the black matrix BM is not arranged may be distinguished from an area in which the black matrix BM is arranged when viewed from a user's view (viewing angle: VA). Accordingly, the reflective color tone of a turned-on display apparatus may be improved, and the clarity of images may be enhanced.

The second area UD may further include a light transmitting area LT compared to the first area NML. Therefore, when the display apparatus is in a turned-off state, the second area UD may be more likely to be visually distinguishable from the first area NML. When the display apparatus is in a turned-off state, it may be advantageous in terms of design to make the second area UD and the first area NML indistinguishable from the user's view (viewing angle: VA).

Referring to FIG. 14, in the case where the black matrices BM are arranged over the slits SL1 and SL2, the black matrices BM may absorb all of the second light VIS. Even if the display apparatus is in a turned-off state, the second light VIS is not directed toward the direction in which the view VA of the user is positioned (see mark X in FIG. 14), and thus the second light VIS may be visually perceived from neither the first area NML nor the second area UD through the view VA of the user. Therefore, an advantage may be obtained in terms of design compared to the case where the color filter overlapping structure CFNS is included.

Referring to FIG. 15, in the state in which the display apparatus is turned off, light may not be emitted from a light-emitting area LE (see mark X in FIG. 15). Therefore, the second light VIS may not be transmitted from the color filters CF1, CF2, and CF3 in the direction of the view VA of the user.

However, even when light is not emitted from the inside of the display panel in the case where the display apparatus is turned off, the color filter overlapping structure CFNS, which is brighter than the black matrix BM, may be more clearly perceived due to external light or the like, as seen from the view VA of the user. The black matrix BM also absorbs the external light, whereas the absorption rate of external light by the color filter overlapping structure CFNS is lower than that by the black matrix BM. Accordingly, the color filter overlapping structure CFNS may be more clearly perceived than the black matrix BM, as seen from the view VA of the user, in the state in which the display apparatus is turned off (comparison between FIGS. 14 and 15).

As described above, the transmittance of the second light VIS through the color filter overlapping structure CFNS may be higher than that of the black matrix BM. Therefore, the second light VIS may not be relatively perceived from the view VA of the user in the case where the black matrix BM is arranged over each of the slits SL1 and SL2. Also, the second light VIS may be relatively clearly perceived, as seen from the view VA of the user, in the case where the color filter overlapping structure CFNS is arranged over each of the slits SL1 and SL2.

Therefore, a distinction between the second area UD and the first area NML may be enhanced in the case where the black matrix BM is arranged, compared to the case where the color filter overlapping structure CFNS is arranged. Because the second area UD is not distinguished from the first area NML, as seen through the view VA of the user, a more advantage may be obtained in terms of design. In other words, in terms of boundary visibility, it may be more advantageous to arrange the black matrices BM over the slits SL1 and SL2.

In the case where the black matrices BM are arranged over the slits SL1 and SL2, a problem arises in that the transmittance of the first light IR deteriorates. However, during the operation of the display apparatus or in the state in which the display apparatus is turned off, reflective color tone may be improved or, alternatively, an advantage may be obtained in terms of design.

In the case where the color filter overlapping structures CFNS are arranged over the slits SL1 and SL2, the transmittance of the first light IR may be enhanced, as described above. However, because the user visually perceives the second area UD from the first area NML, a disadvantage may occur in terms of design, and reflective color tone may deteriorate.

In the display apparatus according to an embodiment of the present specification, a black matrix BM and/or a color filter overlapping structure CFNS may be arranged over each of the slits SL1 and SL2 so as to solve diffraction of light occurring from the slits SL1 and SL2.

In case that only a black matrix BM is arranged, a problem may occur in the transmittance of the first light IR, and in case that only a color filter overlapping structure CFNS is arranged, a problem may occur in terms of reflective color tone and/or design aspects. Accordingly, an embodiment may provide a display apparatus including both the black matrix BM and the color filter overlapping structure CFNS.

The embodiment may solve diffraction of light, and may improve the transmittance of first light IR while reducing a phenomenon in which a second area UD is visually perceived (i.e., a boundary visibility phenomenon). Further, the embodiment may improve the reflective color tone of images while enhancing the sensing performance of the optical element 200.

Referring to FIG. 16, a light-emitting area LE included in each of a first area NML and a second area UD may include first slits SL11 and SL12. The first slits SL11 and SL12 may be formed by a first metal overlapping structure MNS1. A light transmitting area LT included in the second area UD may include a second slit SL2. The second slit SL2 may be formed by a second metal overlapping structure MNS2.

The first metal overlapping structure MNS1 may include a first-first metal overlapping structure MNS11 including a first-first slit SL11, and a first-second metal overlapping structure MNS12 including a first-second slit SL12. The first-first metal overlapping structure MNS11 may comprise metal overlapping structures MNSla and MNS1b spaced apart by the first-first slit SL11. The first-second metal overlapping structure MNS12 may comprise metal overlapping structures MNS1b and MNS1c spaced apart by the first-second slit SL12. The first-first slit SL11 may be arranged to overlap the color filter overlapping structure CFNS in the thickness direction of the display panel 100. The first-second slit SL12 may be arranged to overlap the black matrix BM in the second area UD in the thickness direction of the display panel 100. Although both the first-first slit SL11 and the first-second slit SL12 are illustrated as being formed by the same metal overlapping structure MNS1b, embodiments of the present specification are not limited thereto. For example, the plurality of metal overlapping structures that form a plurality of slits may be multiple independent metal layers that are different from each other.

In the state in which the display apparatus is turned on, first light IR may be emitted from an optical element 200, and second light VIS may be emitted from a light-emitting element EL. Referring to the above description, the first light IR may pass through a color filter overlapping structure CFNS, but the second light VIS may not be transmitted and/or reflected in the direction in which a black matrix BM is arranged (see mark X in FIG. 16).

The transmittance of the first light IR, emitted from the optical element 200, through the black matrix BM may be relatively low. Further, the transmittance of the first light IR through the color filter overlapping structure CFNS may be relatively high.

The second light VIS perceived within the user's view may be relatively better absorbed by the black matrix BM and relatively less absorbed by the color filter overlapping structure CFNS.

In the display apparatus according to an embodiment of the present specification, the black matrix BM may be arranged over any one of the plurality of slits SL11 and SL12, and the color filter overlapping structure CFNS may be arranged over another slit. According to an embodiment of the present specification, the color filter overlapping structure CFNS may be arranged over the first-first slit SL11. The black matrix BM may be arranged over the first-second slit SL12. Although the color filter overlapping structure CFNS may be arranged over the second slit SL2, embodiments of the present specification are not limited thereto. For example, the black matrix BM may be arranged over the second slit SL2. Alternatively, the color filter overlapping structure CFNS may be arranged over any one of a plurality of second slits SL2, and the black matrix BM may be arranged over another second slit. Accordingly, both improved visibility and enhanced transmittance for the first light IR may be achieved.

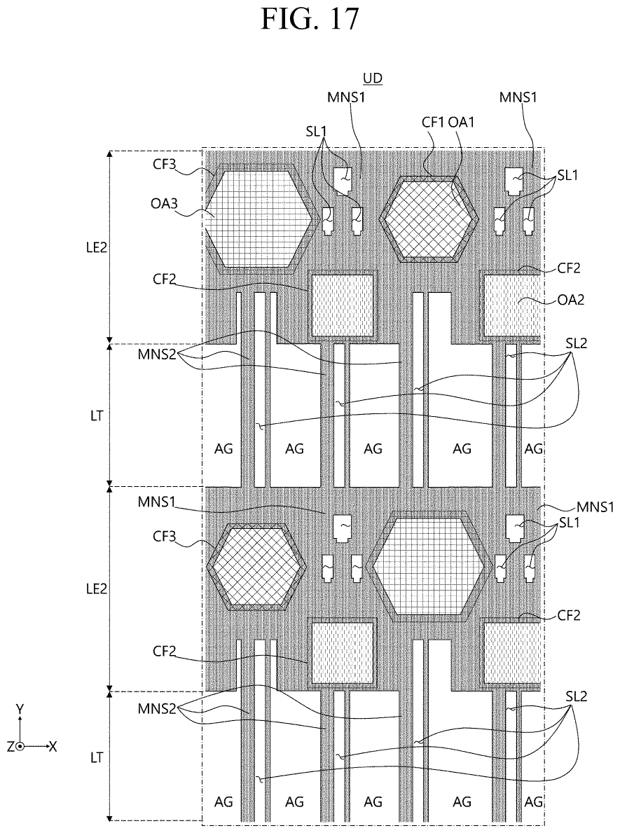

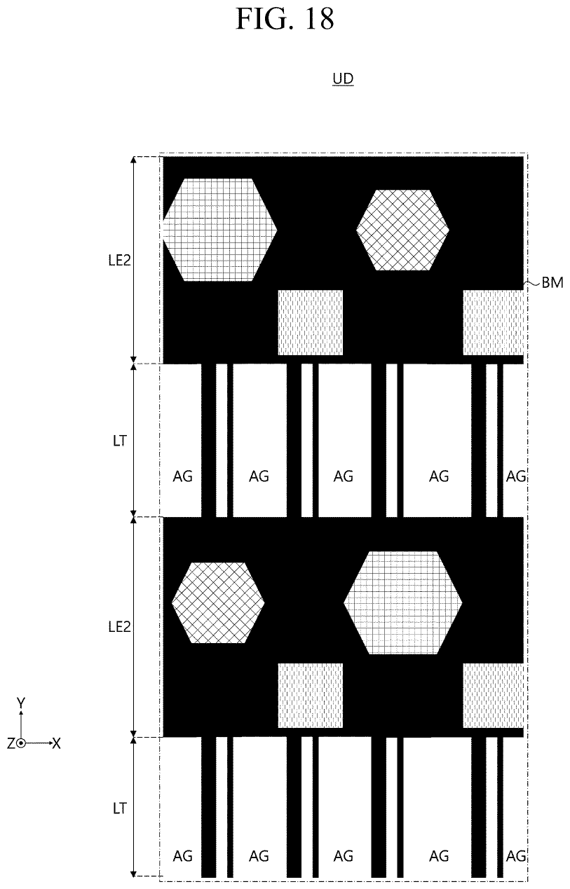

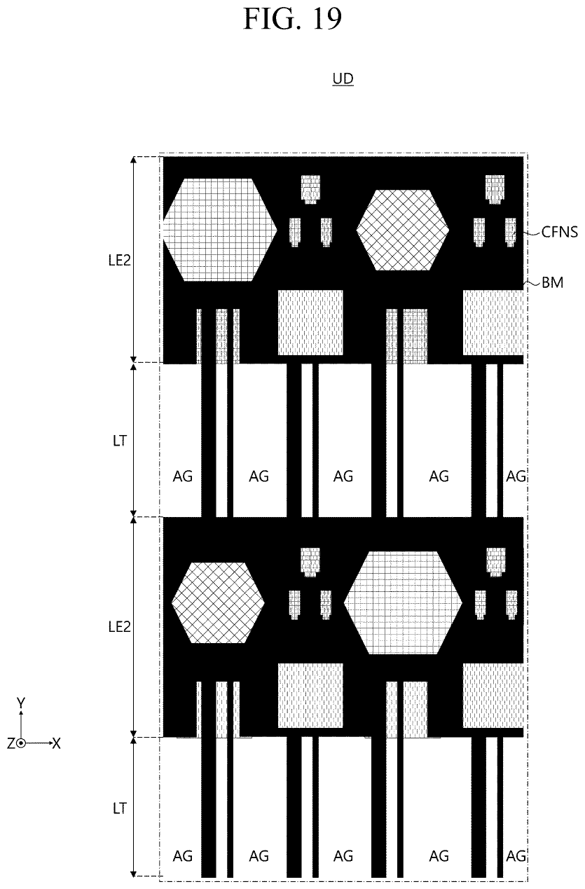

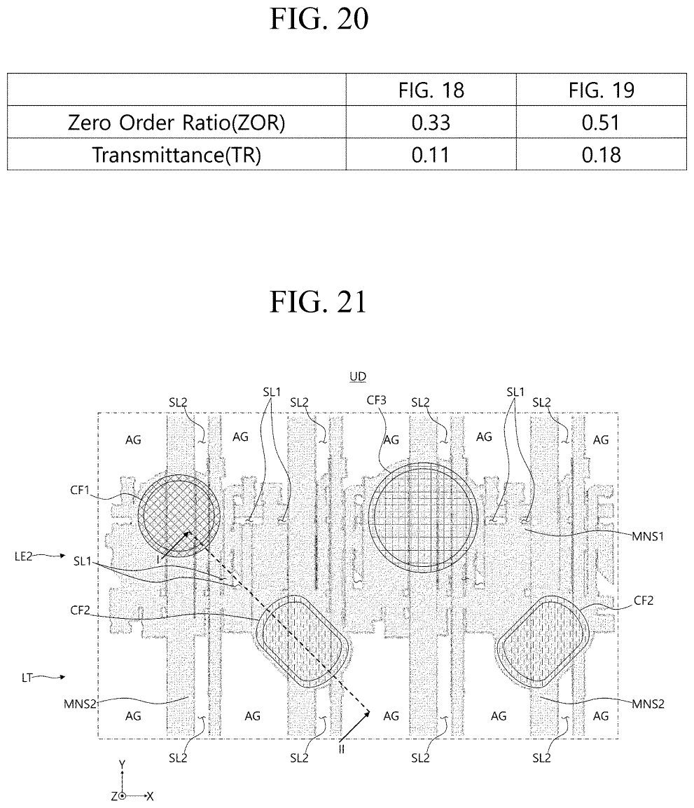

FIG. 17 is a partially enlarged view illustrating an enlarged portion P of FIG. 7. FIG. 18 is a partially enlarged view illustrating an enlarged portion P of FIG. 7 in which a black matrix is arranged in a first slit. FIG. 19 is a partially enlarged view illustrating an enlarged portion P of FIG. 7 in which a black matrix is not arranged in a first slit. FIG. 20 is a table illustrating image clarity and transmittance in embodiments illustrated in FIGS. 18 and 19. FIG. 21 is a plan view illustrating a display apparatus according to another embodiment of the present specification.

Referring to FIGS. 17 and 21, the display apparatus according to an embodiment of the present specification may include a second area UD that includes a light transmitting area LT, having light transmitters AG, and a second light-emitting area LE2. Light may be transmitted through the light transmitters AG, and thus the sensing and/or light receiving performance of an optical element 200 arranged below a display panel may be improved.

A plurality of metal layers may be stacked to form metal overlapping structures MNS1 and MNS2. Although the metal overlapping structures MNS1 and MNS2 may be seen as a single integrated metal layer in the plan view, they may be structures formed by stacking the plurality of metal layers, as will be described later (see FIG. 21).

As described above, the second light-emitting area LE2 may include first slits SL1. The light transmitting area LT may include second slits SL2. Each first slit SL1 may be a space formed by the first metal overlapping structure MNS1 and may be a gap in which none of metal layers overlap each other in a circuit layer. Each second slit SL2 may be a space formed by the second metal overlapping structure MNS2 and may be a gap in which none of metal layers overlap each other in a circuit layer.

In the display apparatus according to the embodiment of the present specification, a plurality of metal layers included in each of the illustrated metal overlapping structures MNS1 and MNS2 may be metal layers defined in the circuit layer.

For example, electrodes (e.g., an anode electrode, a cathode electrode, etc.) of a light-emitting element layer may be arranged on the first slits SL1, and the first slits SL1 may be gaps occurring in case that none of a plurality of metal layers present in the circuit layer of the second light-emitting area LE2 overlap each other.

For example, electrodes (e.g., an anode electrode, a cathode electrode, etc.) of the light-emitting element layer may be arranged over the second slits SL2, and the second slits SL2 may be gaps occurring in case that none of a plurality of metal layers present in the circuit layer of the light transmitting area LT overlap each other. Although spaces that can be defined as slits SL1 and SL2 are denoted by the symbol “˜”, embodiments of the present specification are not limited thereto.

Color filters CF1, CF2, and CF3 may be formed to be larger than opening areas OA1, OA2, and OA3. Light may be emitted from regions in which the color filters CF1, CF2, and CF3 overlap the opening areas OA1, OA2, and OA3, respectively.

Referring to FIG. 18, a black matrix BM may be arranged on the first metal overlapping structure MNS1. For example, in the area of the first metal overlapping structure MNS1 overlapping the color filters CF1, CF2, and CF3, the black matrix BM may be arranged. However, the black matrix BM may not be arranged in a region that does not overlap the opening areas OA1, OA2, and OA3 in the foregoing area. Accordingly, light may be emitted to allow the user to perceive the emitted light.

In an embodiment, the black matrix BM may be arranged over the first slit formed by the first metal overlapping structure MNS1. Further, the black matrix BM may also be arranged in at least a portion of each light transmitter AG.

As described above, in case that only the black matrix BM is arranged, reflective color tone or the like may be improved, but the transmittance of first light, the clarity of images, or the like may deteriorate.

Referring to FIG. 19, in an embodiment, color filter overlapping structures CFNS may be arranged over first slits and at least a portion of each of light transmitters AG. According to an embodiment of the present specification, there is an advantage in that the sensing performance of the optical element 200 may also be enhanced by ensuring the transmittance of first light while suitably improving reflective color tone.

Referring to FIG. 20, it is verified that both a ZOR value indicating image clarity and a TR value indicating transmittance are improved in an embodiment (in FIG. 19) in which color filter overlapping structures are arranged, together with the black matrix, over slits, compared to the embodiment illustrated in FIG. 18.

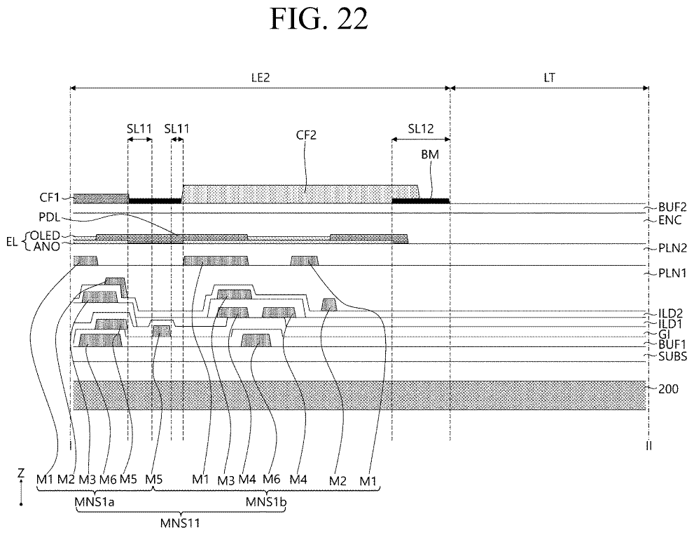

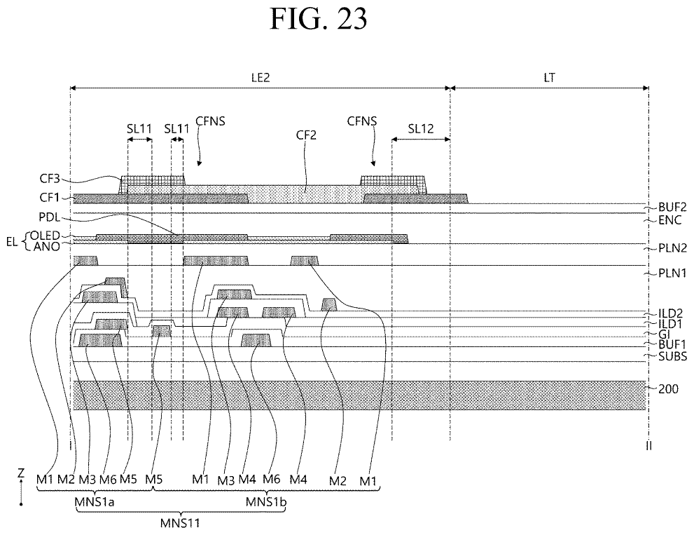

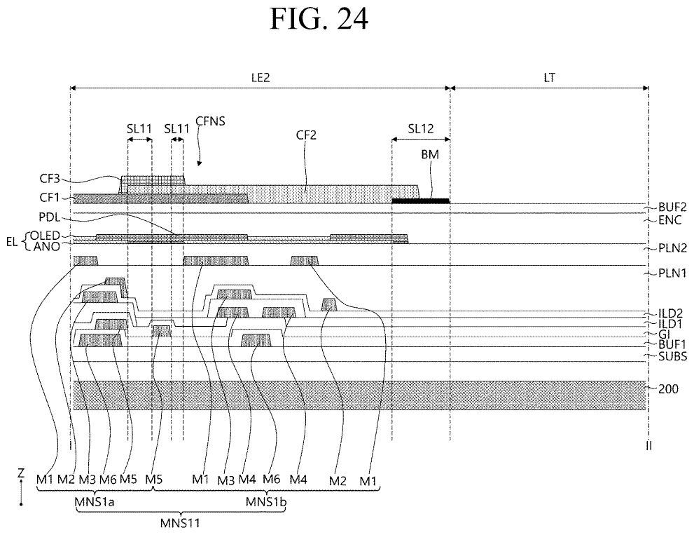

FIG. 22 is a sectional view taken along line I-II of FIG. 21 in a structure in which black matrices are arranged in slits. FIG. 23 is a sectional view taken along line I-II of FIG. 21 in a structure in which color filter overlapping structures are arranged in slits. FIG. 24 is a sectional view taken along line I-II of FIG. 21 in a structure in which a color filter overlapping structure and a black matrix are arranged in slits.

Referring to FIG. 22, each of a second light-emitting area LE2 and a light transmitting area LT may include a substrate SUBS, a first buffer layer BUF1, a gate insulating layer GI, interlayer insulating layers ILD1 and ILD2, planarization layers PLN1 and PLN2, a light-emitting element layer in which light-emitting elements EL are arranged, an encapsulation layer ENC, a second buffer layer BUF2, and the like.

In the second light-emitting area LE2, a first-first metal overlapping structure MNS11 including a plurality of slits SL11 and SL12 may be arranged. When a plurality of metal layers M1 to M6 included in the first-first metal overlapping structure MNS11 are formed at different thicknesses, lengths, widths, etc. in different layers, the plurality of slits SL11 and SL12 may be formed. Each slit may be defined as a space that does not overlap the plurality of metal layers M1 to M6 in the planar direction of the display panel.

In addition, the second light-emitting area LE2 may include various electrodes or signal wires.

The substrate SUBS may include a plurality of substrates SUBS and an intermediate layer interposed between the substrates SUBS. The intermediate layer may be, for example, an inorganic layer, thereby blocking moisture penetration into the intermediate layer.

Lower protective metal M6 may be arranged on the substrate SUBS. The lower protective metal M6 may be arranged below an active layer M5 of a transistor. The lower protective metal M6 may function to protect the active layer M5 sensitive to light.

The first buffer layer BUF1 may have a single-layer structure or a multi-layer structure. When the first buffer layer BUF1 has the multi-layer structure, it may include a multi-buffer layer and an active buffer layer.

A plurality of transistors, storage capacitors, and various electrodes or signal wires may be formed on the first buffer layer BUF1.

The transistors formed on the first buffer layer BUF1 may be made of the same material, and may be located on the same layers, but the transistors are not limited thereto.

A transistor (T) may include the active layer M5, a first electrode M1, a second electrode M2, and a gate electrode M4. The active layer M5 may be arranged on the first buffer layer BUF1. The gate insulating layer GI may be arranged on the active layer M5. The gate electrode M4 may be arranged on the gate insulating layer GI, and the interlayer insulating layers ILD1 and ILD2 may be arranged below and on the gate electrode M4.

The active layer M5 may include a channel region overlapping the gate electrode M4, a source connection region located on one side of the channel region, and a drain connection region located on the other side of the channel region. The active layer M5 may contain an oxide semiconductor material. For example, the oxide semiconductor material may include Indium Gallium Zinc Oxide (IGZO), Indium Gallium Zinc Tin Oxide (IGZTO), ZnO, CdO, InO, Zinc Tin Oxide (ZTO), Zinc Indium Tin Oxide (ZITO), and the like. The active layer M5 may contain a silicon-based semiconductor material. For example, the silicon-based semiconductor material may contain Low-Temperature Polycrystalline Silicon (LTPS) or the like.

The first electrode M1 and the second electrode M2 of the transistor may be arranged on the gate insulating layer GI. The first electrode M1 and the second electrode M2 of the transistor may be connected to source connection region and drain connection region of the active layer M5, respectively, through via holes in the gate insulating layer GI.

The planarization layers PLN1 and PLN2 may be arranged on the interlayer insulating layers ILD1 and ILD2. The planarization layers PLN1 and PLN2 may be arranged to cover the first electrode M1 and the second electrode M2 of the transistor.

The light-emitting element EL may be formed in the light-emitting element layer. The light-emitting element EL may be driven by a driving transistor. In an embodiment, the light-emitting element EL may be an organic light-emitting element. In this case, the light-emitting element EL may include an anode electrode ANO, a cathode electrode, and a light-emitting layer OLED interposed between the anode electrode ANO and the cathode electrode. The light-emitting layer OLED may include an organic compound layer. The organic compound layer may include, but is not limited to, a hole injection layer (HIL), a hole transport layer (HTL), an emission layer (EML), an electron transport layer (ETL), and an electron injection layer (EIL).

When a voltage is applied to the anode electrode ANO and the cathode electrode of the light-emitting element EL, holes having passed through the hole transport layer and electrons having passed through the electron transport layer may be shifted to the emission layer to form excitons, thus enabling light having a wavelength band of visible light to be emitted from the emission layer. The light-emitting element EL may have a tandem structure in which a plurality of emission layers are stacked. The light-emitting element EL having the tandem structure may improve the luminance and lifespan of pixels. The light-emitting element layer may emit light of any one color among red, green, and blue, but it is not limited thereto. When the light-emitting element layer emits white light, light of any one of red, green, and blue may be emitted through the color filters CF1 or CF2 arranged above the light-emitting element layer.

The pixel defining layer PDL may be arranged on the anode electrode ANO. The pixel defining layer PDL may overlap at least a portion of the anode electrode ANO. The light-emitting layer OLED may be arranged on the anode electrode ANO. The cathode electrode may be arranged on the light-emitting layer OLED.

The encapsulation layer may be arranged on the cathode electrode. The encapsulation layer may be a layer that prevents moisture or oxygen from penetrating into the light-emitting element EL arranged under the encapsulation layer. The encapsulation layer may prevent moisture or oxygen from penetrating into the light-emitting layer OLED that may include an organic layer. The encapsulation layer may be formed in a single-layer structure or a multi-layer structure. The encapsulation layer may include a first encapsulation layer, a second encapsulation layer, and a third encapsulation layer. The first encapsulation layer and the third encapsulation layer may be inorganic layers, and the second encapsulation layer may be an organic layer. Because the second encapsulation layer is formed of the organic layer, the second encapsulation layer may function as a planarization layer.

The color filters CF1 and CF2 may be formed to be substantially facing the light-emitting layer OLED. As described above, each of the color filters CF1 and CF2 may implement any one color selected from the group consisting of red, green, and blue. For this operation, the wavelength band of incident light may be selectively converted into a wavelength band corresponding to visible light.

In the display apparatus according to an embodiment of the present specification, a black matrix BM may be arranged in each of a first-first slit SL11 and a first-second slit SL12. Accordingly, visibility under external light may be improved, and reflective color tone may be enhanced, thus enhancing image quality. Also, a phenomenon in which the boundaries of a turned-off display apparatus are visually perceived may be reduced.

Referring to FIG. 23, in the display apparatus according to an embodiment of the present specification, a color filter overlapping structure CFNS may be arranged in each of a first-first slit SL11 and a first-second slit SL12. The color filter overlapping structure according to an embodiment may include a first color filter CF1, a second color filter CF2 arranged on the first color filter CF1, and a third color filter CF3 arranged on the second color filter CF2. The first-first slit SL11 and the first-second slit SL12 in the second light-emitting area LE2 may be arranged to overlap the color filter overlapping structure CFNS in the thickness direction of the display panel. Accordingly, there is an advantage in that the transmittance of light having an infrared wavelength band may be improved, thus enhancing the sensing performance of the optical element 200.

Referring to FIG. 24, in the display apparatus according to an embodiment of the present specification, a color filter overlapping structure CFNS may be arranged in a first-first slit SL11. A black matrix BM may be arranged in a first-second slit SL12. The color filter overlapping structure according to an embodiment may include a first color filter CF1, a second color filter CF2 arranged on the first color filter CF1, and a third color filter CF3 arranged on the second color filter CF2. Accordingly, there is an advantage in that the transmittance of light having an infrared wavelength band may be improved, thus enhancing the sensing performance of the optical element 200. Along with this advantage, an advantage of enhancing color reproduction through the improvement of reflective color tone may also be obtained. Furthermore, the display apparatus may be driven at low power through the enhancement of color reproduction.

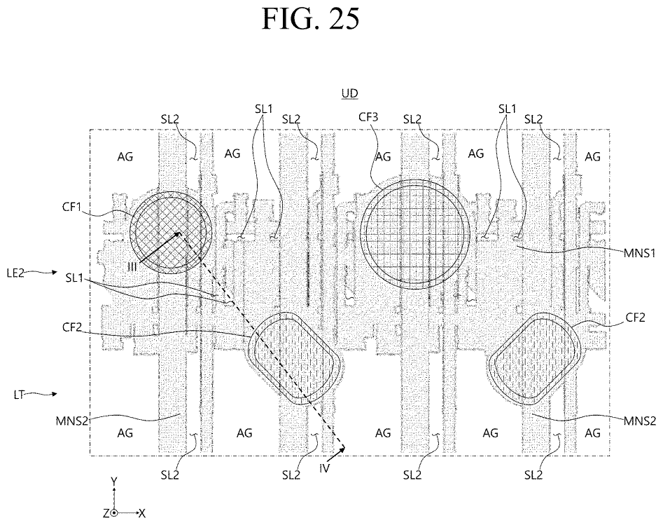

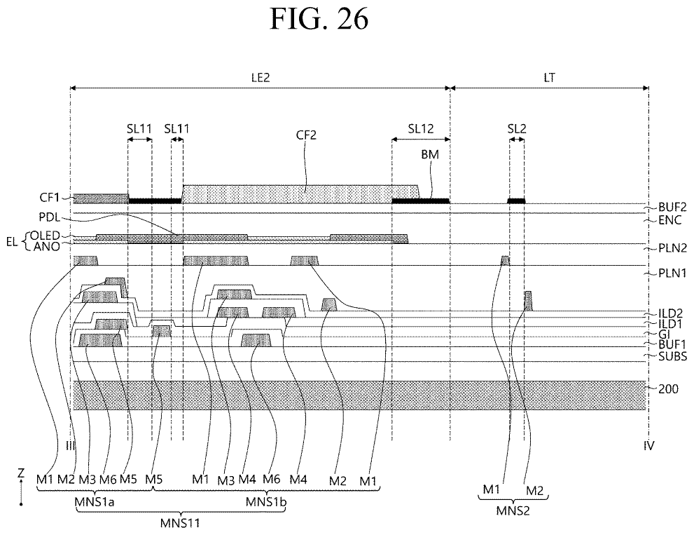

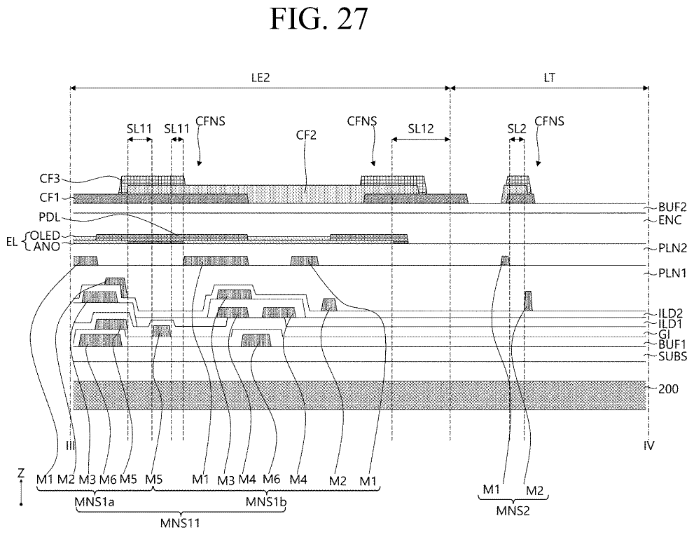

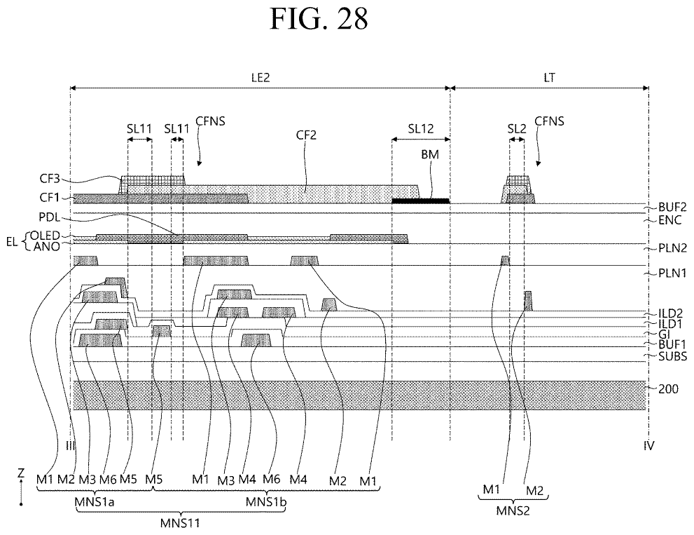

FIG. 25 is a plan view illustrating FIG. 18 with the section line III-IV. FIG. 26 is a sectional view taken along line III-IV of FIG. 25 in a structure in which black matrices are arranged in slits. FIG. 27 is a sectional view taken along line III-IV of FIG. 25 in a structure in which color filter overlapping structures are arranged in slits. FIG. 28 is a sectional view taken along line III-IV of FIG. 25 in a structure in which a color filter overlapping structure and a black matrix are arranged in slits.

Referring to FIG. 26, in the display apparatus according to an embodiment of the present specification, a black matrix BM may be arranged in each of a first-first slit SL11, a first-second slit SL12, and a second slit SL2. The second slit SL2 may be arranged to overlap the black matrix BM in the thickness direction of the display panel. Accordingly, visibility under external light may be improved, and reflective color tone may be enhanced, thus enhancing image quality. Also, a phenomenon in which the boundaries of a turned-off display apparatus are visually perceived may be reduced.

Referring to FIG. 27, in the display apparatus according to an embodiment of the present specification, a color filter overlapping structure CFNS may be arranged in each of a first-first slit SL11, a first-second slit SL12, and a second slit SL2. The color filter overlapping structure according to an embodiment may include a first color filter CF1, a second color filter CF2 arranged on the first color filter CF1, and a third color filter CF3 arranged on the second color filter CF2. Third color filter CF3 may be arranged to overlap the second color filter CF2 in the thickness direction of the display panel. The second slit SL2 may be arranged to overlap the color filter overlapping structure CFNS in the thickness direction of the display panel. Accordingly, there is an advantage in that the transmittance of light having an infrared wavelength band may be improved, thus enhancing the sensing performance of the optical element 200.

Referring to FIG. 28, in the display apparatus according to an embodiment of the present specification, a color filter overlapping structure CFNS may be arranged in a first-first slit SL11. A black matrix BM may be arranged in a first-second slit SL12. The color filter overlapping structure CFNS may be arranged in a second slit SL2. The color filter overlapping structure according to an embodiment may include a first color filter CF1, a second color filter CF2 arranged on the first color filter CF1, and a third color filter CF3 arranged on the second color filter CF2. Accordingly, there is an advantage in that the transmittance of light having an infrared wavelength band may be improved, thus enhancing the sensing performance of the optical element 200. Along with this advantage, there is an advantage in which reflective color tone may be improved and color reproduction may also be enhanced due to the black matrix BM.

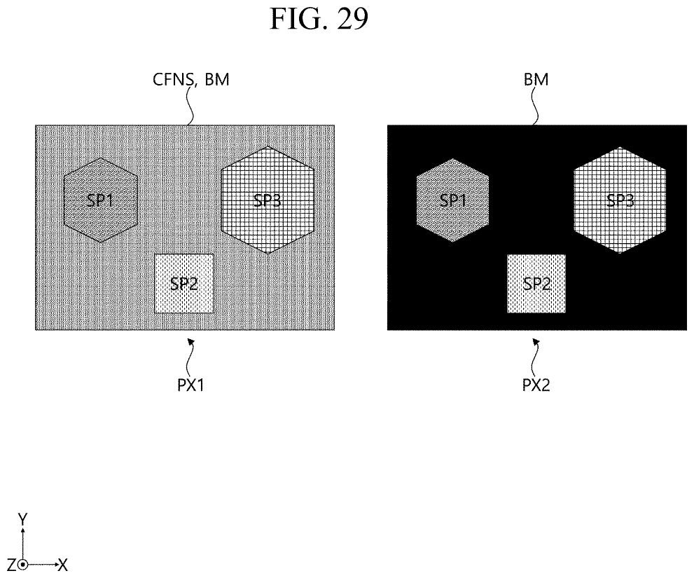

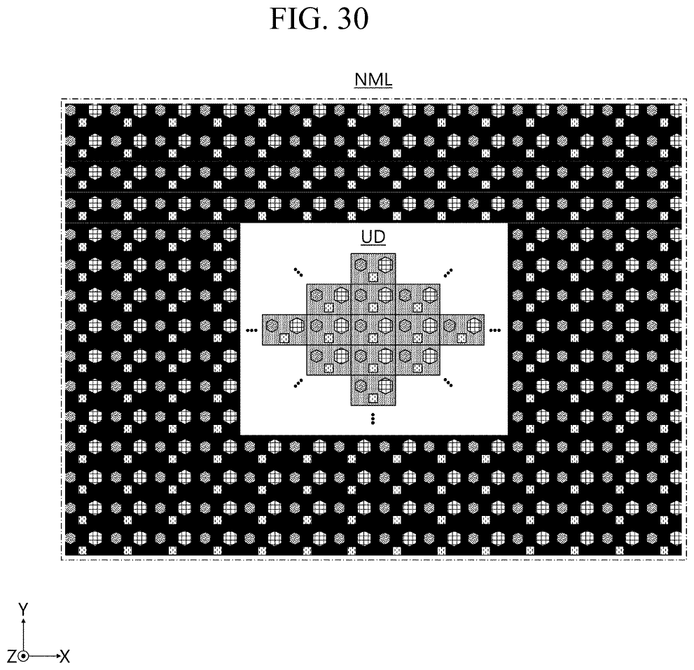

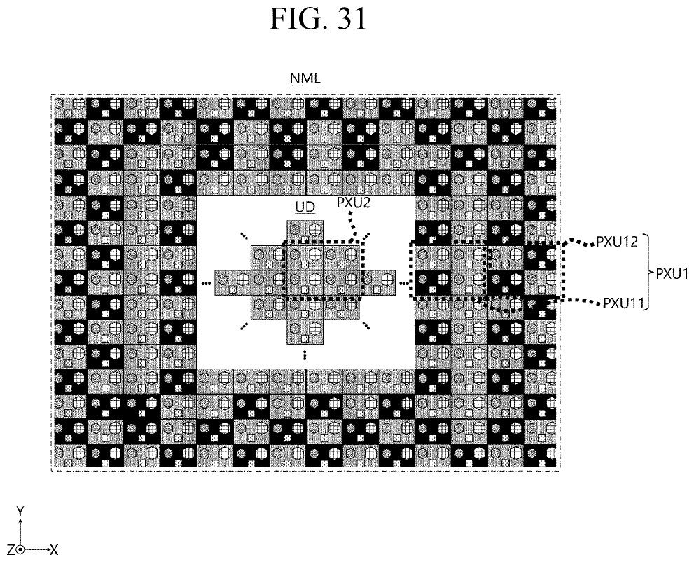

FIG. 29 is a plan view illustrating pixels according to an embodiment of the present specification. FIG. 30 is a plan view illustrating a display apparatus in which pixels are arranged according to an embodiment of the present specification. FIG. 31 is a plan view illustrating a display apparatus according to another embodiment of the present specification.

Referring to FIG. 29, the display apparatus according to an embodiment of the present specification may include a first pixel PX1 and a second pixel PX2. The first pixel PX1 may include a first sub-pixel SP1, a second sub-pixel SP2, and a third sub-pixel SP3. The second pixel PX2 may include a first sub-pixel SP1, a second sub-pixel SP2, and a third sub-pixel SP3.

The first pixel PX1 may include a color filter overlapping structure CFNS and a black matrix BM. The second pixel PX2 may include a black matrix BM. For example, the density of the color filter overlapping structure CFNS of the first pixel may be greater than that of the second pixel PX2.

Referring to FIG. 30, the display apparatus according to an embodiment of the present specification may include a second area UD including first pixels PX1 and a first area NML including second pixels PX2. Each of the first area NML and the second area UD may comprise a color filter overlapping structure.

In the second area UD, the second density of the color filter overlapping structure may be defined. The second density may be the area of the color filter overlapping structure per second unit pixel arranged in the second area UD. The second unit pixel may include a plurality of first pixels PX1.

In the first area NML, the first density of the color filter overlapping structure may be defined. The first density may be the area of the color filter overlapping structure per first unit pixel arranged in the first area NML. The first unit pixel may include a plurality of second pixels PX2.

In an embodiment, the second density may be different from the first density. Since the color filter overlapping structure is arranged for the purpose of improving the transmittance of first light compared to the black matrix, the color filter overlapping structure may be preferentially arranged in an area requiring high transmittance of first light. Therefore, for example, the second density may be greater than the first density.

When the first area NML and the second area UD are configured as in the case of the above-described embodiment, the problem of the visible perception of boundaries between the first area NML and the second area UD may occur. As described above, the color filter overlapping structure is disadvantageous compared to the black matrix in terms of reflective color tone. Accordingly, when the color filter overlapping structure is included only in the second area UD, boundaries between the first area NML and the second area UD may be perceived by the user, thus leading to a disadvantage in design.

Referring to FIG. 31, the display apparatus according to an embodiment of the present specification may include a second area UD including a first pixel PX1 and a first area NML including a first pixel PX1 and a second pixel PX2.

In the second area UD, the second density of the color filter overlapping structure may be defined. The second density may be the area of the color filter overlapping structure per second unit pixel PXU2 arranged in the second area UD. The second unit pixel PXU2 may include a plurality of first pixels PX1.

In the first area NML, the first density of the color filter overlapping structure may be defined. The first density may be the area of the color filter overlapping structure per first unit pixel PXU1 arranged in the first area NML. The first unit pixel PXU1 may include a first pixel PX1 and a second pixel PX2. In an embodiment, the number of pixels included in the first unit pixel PXU1 may be identical to the number of pixels included in the second unit pixel PXU2.

In an embodiment, the second density may be different from the first density. Since the color filter overlapping structure is arranged for the purpose of improving the transmittance of first light compared to the black matrix, the color filter overlapping structure may be preferentially arranged in an area requiring high transmittance of first light. Therefore, for example, the second density may be greater than the first density.

The first density may change in the first area NML. In a direction from the second area UD to the first area NML (e.g., a direction toward a first direction or an X-axis direction), the first density may change, for example, decrease. The first unit pixel PXU1 may include a first-first unit pixel PXU11 and a first-second unit pixel PXU12. Although the first-second unit pixel PXU12 may be arranged in the first direction from the first-first unit pixel PXU11, embodiments of the present specification are not limited thereto.

The number of first pixels PX1 included in the first-first unit pixel PXU11 and the number of first pixels PX1 included in the first-second unit pixel PXU12 may be different from each other. For example, the number of first pixels PX1 included in the first-first unit pixel PXU11 may be greater than the number of first pixels PX1 included in the first-second unit pixel PXU12.

Because the boundary between the first area NML and the second area UD can be visually perceived due to the density of the color filter overlapping structure, such a disadvantage may be solved by gradually adjusting the density according to an embodiment of the present specification. According to embodiments of the present specification, there can be provided a display apparatus, which has improved first light transmittance, enhances reflective color tone and color reproduction, and reduces a phenomenon in which a boundary between areas is visually perceived, thereby obtaining an advantage from a design aspect.

According to various embodiments of the present specification, a pixel density or resolution of the second area may be the same or lower than that of the first area.

According to various embodiments of the present specification, the second area includes pixel groups spaced apart from each other and light transmitters arranged between neighboring pixel groups, and the light transmitters may be regions in which pixels are not arranged and located in the light transmitting area.

According to various embodiments of the present specification, the optical element may be arranged under a rear surface of the display panel to overlap the second area.

According to various embodiments of the present specification, the first unit pixel includes a first-first unit pixel and a first-second unit pixel, and a number of pixels included in the first-first unit pixel and a number of pixels included in the first-second unit pixel may be different from each other.

Although embodiments of the present invention have been described in more detail with reference to the accompanying drawings, the present invention is not necessarily limited to these embodiments, and may be variously modified without departing from the technical idea of the present invention.

Accordingly, the embodiments disclosed herein are not intended to limit the technical spirit of the present invention but merely illustrate it, and the scope of the technical idea of the present invention is not limited by these embodiments.

Therefore, it should be understood that the embodiments described above are illustrative in all respects and are not limited.

The scope of protection of the present invention should be interpreted based on the claims, and all technical ideas within an equivalent scope thereof should be interpreted as being included in the scope of the present invention.

What is claimed is:

1. A display apparatus, comprising:
an optical element configured to emit light to outside or sense light from the outside; and
a display panel comprising a first area including a first light-emitting area and a second area including a second light-emitting area and a light transmitting area,
wherein the second area comprises a color filter overlapping structure, and
wherein the color filter overlapping structure comprises a first color filter and a second color filter arranged to overlap the first color filter in a thickness direction of the display panel.

2. The display apparatus of claim 1, wherein the second area further comprises a black matrix.

3. The display apparatus of claim 1, wherein:
the second area further comprises a metal overlapping structure including a slit, and
the slit overlaps the color filter overlapping structure in the thickness direction.

4. The display apparatus of claim 1, wherein:
the second light-emitting area comprises a first metal overlapping structure including a first slit, and
the first slit overlaps the color filter overlapping structure in the thickness direction.

5. The display apparatus of claim 4, wherein the light transmitting area comprises a second metal overlapping structure including a second slit.

6. The display apparatus of claim 4, wherein:
the second area further comprises a black matrix, and
the first metal overlapping structure comprises a first-first metal overlapping structure including a first-first slit and a first-second metal overlapping structure including a first-second slit,
the first-first slit overlaps the color filter overlapping structure in the thickness direction, and
the first-second slit overlaps the black matrix in the thickness direction.

7. The display apparatus of claim 6, wherein the light transmitting area comprises a second metal overlapping structure including a second slit.

8. The display apparatus of claim 7, wherein the second slit overlaps the color filter overlapping structure in the thickness direction.

9. The display apparatus of claim 7, wherein the second slit overlaps the black matrix in the thickness direction.

10. The display apparatus of claim 1, wherein the color filter overlapping structure further comprises a third color filter overlapping the second color filter in the thickness direction.

11. A display apparatus, comprising:
an optical element configured to emit light to outside or sense light from the outside; and
a display panel comprising a first area including a plurality of pixels and a second area including a plurality of pixels and a light transmitting area,
wherein each of the first area and the second area comprises a color filter overlapping structure, and
wherein the color filter overlapping structure in the second area has a second density different from a first density of the color filter overlapping structure in the first area.

12. The display apparatus of claim 11, wherein the second density is greater than the first density.

13. The display apparatus of claim 11, wherein:
the second density is an area of the color filter overlapping structure per second unit pixel arranged in the second area, and
the first density is an area of the color filter overlapping structure per first unit pixel arranged in the first area.

14. The display apparatus of claim 13, wherein a number of pixels included in the first unit pixel is identical to a number of pixels included in the second unit pixel.

15. The display apparatus of claim 11, wherein the first density changes in a direction from the second area to the first area.

16. The display apparatus of claim 15, wherein the first density decreases in a direction from the second area to the first area.

17. The display apparatus of claim 11, wherein the color filter overlapping structure comprises a first color filter and a second color filter overlapping the first color filter in a thickness direction of the display panel.

18. The display apparatus of claim 11, wherein each of the first area and the second area further comprises a black matrix.

19. The display apparatus of claim 17, wherein:
each of the first area and the second area comprises a metal overlapping structure including a slit, and
the slit is overlaps the color filter overlapping structure in the thickness direction.

20. The display apparatus of claim 17, wherein:
each of the first area and the second area comprises a first metal overlapping structure including a first slit,
the light transmitting area comprises a second metal overlapping structure including a second slit, and
the first slit is arranged to overlap the color filter overlapping structure in the thickness direction.
